(19) United States
(12) Patent Application Publication
(10) Pub. No.: US 2020/0285144 A1
(43) Pub. Date: Sep. 10, 2020

(54) MASK BLANK, TRANSFER MASK, AND METHOD FOR MANUFACTURING SEMICONDUCTOR DEVICE

(71) Applicant: HOYA CORPORATION, Tokyo (JP)

(72) Inventors: Hitoshi MAEDA, Tokyo (JP); Hiroaki SHISHIDO, Tokyo (JP)

(73) Assignee: HOYA CORPORATION, Tokyo (JP)

(21) Appl. No.: 16/648,933

(22) PCT Filed: Sep. 6, 2018
(86) PCT No.: PCT/JP2018/033015

§ 371 Date: Mar. 19, 2020

(30) Foreign Application Priority Data
Sep. 21, 2017 (JP) 2017-181304

(51) Int. Cl. G03F 1/32; G03F 7/20

(52) U.S. Cl. CPC G03F 1/32; G03F 7/2006

(57) ABSTRACT

In a mask blank in which a thin film formed of a material consisting of silicon and nitrogen is formed on a transparent substrate, when the thin film is analyzed by secondary ion mass spectrometry to obtain in-depth distribution of a secondary ion intensity of silicon in counts per second, a slope of the secondary ion intensity of silicon with respect to depth in a direction toward the transparent substrate is less than one hundred fifty counts per second per nanometer in an internal region of the thin film other than a substrate neighborhood region and a surface region.

### CROSS REFERENCE TO RELATED APPLICATIONS

This application is a National Stage of International Application No. PCT/JP2018/033015 filed Sep. 6, 2018, which claims priority to Japanese Patent Application No. 2017-181304 filed Sep. 21, 2017, and the contents of which are incorporated by reference in its entirety.

### TECHNICAL FIELD

This disclosure relates to a mask blank, a transfer mask, and a method for manufacturing a semiconductor device using the transfer mask. In particular, this disclosure relates to a mask blank to be suitably used in case where short-wavelength light having a wavelength of 200 nm or less is used as exposure light, a transfer mask, and a method for manufacturing a semiconductor device.

### BACKGROUND ART

Generally, in a manufacturing process of a semiconductor device, a fine pattern is formed using a photolithography method. In forming the fine pattern, a number of substrates called transfer masks (photomasks) are commonly used. The transfer mask generally has a fine pattern formed on a transparent glass substrate and comprising a metal thin film or the like. In manufacture of the transfer mask, the photolithography method is used also.

The transfer mask serves as an original plate for transferring the same fine pattern in large quantities. Therefore, dimensional accuracy of the pattern formed on the transfer mask directly affects dimensional accuracy of a fine pattern to be formed using the transfer mask. In recent years, there is a remarkable progress in miniaturization of a pattern of the semiconductor device. Correspondingly, the mask pattern formed on the transfer mask is required to be miniaturized and to have higher pattern accuracy. On the other hand, in addition to the miniaturization of the pattern on the transfer mask, there is a progress in shortening a wavelength of an exposure light source used in photolithography. Specifically, with respect to the exposure light used for manufacture of the semiconductor device, shortening of the wavelength advances from a KrF excimer laser (wavelength: 248 nm) to an ArF excimer laser (wavelength: 193 nm) in recent years.

As a type of the transfer mask, a phase shift mask is known in addition to an existing binary mask having a light shielding film pattern formed on a transparent substrate and made of a chromium-based material. As the phase shift mask, various types are known. As one of the types, a halftone phase shift mask is known which is suitable for transfer of a high-resolution pattern such as holes and dots. The halftone phase shift mask comprises a light semi-transmissive film pattern formed on a transparent substrate and having a predetermined phase shift amount (typically, about 180 degrees) and a predetermined transmittance (typically, approximately 1 to 20%). The light semi-transmissive film (phase shift film) may comprise a single layer or multiple layers.

For the phase shift film of the halftone phase shift mask, a transition metal silicide-based material such as molybdenum silicide (MoSi) is widely used. However, as disclosed in Patent Document 1, it has recently been found out that a MoSi-based film is low in resistance (so-called ArF lightfastness) against exposure light of the ArF excimer laser (wavelength: 193 nm). Specifically, in case of the phase shift mask using the transition metal silicide-based material such as MoSi, irradiation with the ArF excimer laser as the exposure light source causes a phenomenon that the transmittance or the phase difference varies and, further, a line width changes (thickens).

Patent Document 2, Patent Document 3, and so on disclose SiNx as a material for forming the phase shift film.

### PRIOR ART DOCUMENT(S)

### Patent Document(s)

Patent Document 1: JP 2010-217514 A

Patent Document 2: JP H8-220731 A

Patent Document 3: JP 2014-137388 A

### SUMMARY OF THE DISCLOSURE

### Problem to be Solved by the Disclosure

Patent Document 3 mentioned above describes that a MoSi-based film has low ArF lightfastness because transition metal (Mo) in the film is photoexcited and destabilized due to irradiation with an ArF excimer laser. In Patent Document 3, SiNx which is a material containing no transition metal is used as a material for forming a phase shift film.

Thus, by using a SiNx-based material containing no transition metal as the material of the phase shift film, it is certainly possible to improve the ArF lightfastness. In the meanwhile, a life duration of a mask has heretofore been determined by the number of times of mask cleaning for the purpose of eliminating haze occurring in the transfer mask. However, because of a decrease in number of times of mask cleaning as a result of recent improvement for the purpose of haze mitigation and under the influence of an increase in manufacturing cost of the transfer mask, a period of repeated use of the transfer mask is extended and, correspondingly, a cumulative exposure time is considerably prolonged. Accordingly, the problem of lightfastness against the short-wavelength light such as the ArF excimer laser particularly has become apparent as a more significant problem. From the above-mentioned background, it is desired to further prolong the life duration of the transfer mask including the phase shift mask.

This disclosure has been made in order to solve the above-mentioned existing problem and a first aspect thereof is to provide a mask blank considerably improved in lightfastness against exposure light having a wavelength of 200 nm or less.

A second aspect of this disclosure is to provide, by using the above-mentioned mask blank, a transfer mask which is considerably improved in lightfastness against exposure light having a wavelength of 200 nm or less and which is stable in quality even after a long period of use.

A third aspect of this disclosure is to provide a method for manufacturing a semiconductor device, which is capable of carrying out high-accuracy pattern transfer to a resist film on a semiconductor substrate by using the above-mentioned transfer mask.

### Means to Solve the Problem

In order to solve the above-mentioned problems, the present inventors studied, in regard to a mask blank having a thin film formed on a transparent substrate and adapted to form a transfer pattern, about a material containing no transition metal and containing silicon and oxygen as a material forming the thin film. In particular, the inventors focused on a bonding state of silicon and nitrogen constituting the thin film and, as a result of continuing diligent studies, completed this disclosure.

Specifically, in order to solve the above-mentioned problem, this disclosure has following structures.

(Structure 1)

A mask blank comprising a transparent substrate on which a thin film for forming a transfer pattern is provided, wherein the thin film is formed of a material consisting of silicon and nitrogen or a material consisting of silicon, nitrogen, and one or more elements selected from metalloid elements and non-metal elements, and wherein, when the thin film is analyzed by secondary ion mass spectrometry to obtain in-depth distribution of a secondary ion intensity of silicon, a slope of the secondary ion intensity [Counts/sec] of silicon with respect to a depth [nm] in a direction towards the transparent substrate is less than 150 [(Counts/sec)/nm] in an internal region of the thin film except a neighborhood region of the thin film near an interface with the transparent substrate and a surface region of the thin film that faces away from the transparent substrate.

(Structure 2)

The mask blank according to structure 1, wherein the surface region is a region extending over a range from a surface of the thin film that faces away from the transparent substrate to a depth of 10 nm towards the transparent substrate.

(Structure 3)

The mask blank according to structure 1 or 2, wherein the neighborhood region is a region extending over a range from the interface with the transparent substrate to a depth of 10 nm towards the surface region.

(Structure 4)

The mask blank according to any one of structures 1 to 3, wherein the in-depth distribution of the secondary ion intensity of silicon is obtained under measurement conditions that a primary ion species is Cs⁺, a primary accelerating voltage is 2.0 kV, and a primary ion irradiation area is an inside region of a square of 120 μm on a side.

(Structure 5)

The mask blank according to any one of structures 1 to 4, wherein the surface region has an oxygen content greater than that in a region of the thin film except the surface region.

(Structure 6)

The mask blank according to any one of structures 1 to 5, wherein the thin film is formed of a material consisting of silicon, nitrogen, and a non-metal element or elements.

(Structure 7)

The mask blank according to structure 6, wherein a nitrogen content in the thin film is 50 atomic % or more.

(Structure 8)

The mask blank according to any one of structures 1 to 7, wherein the thin film is a phase shift film having a function of transmitting exposure light of an ArF excimer laser (wavelength of 193 nm) at a transmittance of 1% or more and a function of causing the exposure light having been transmitted through the thin film to have a phase difference of 150 degrees or more and 190 degrees or less with respect to the exposure light transmitted through air for the same distance as a thickness of the thin film.

(Structure 9)

The mask blank according to structure 8, comprising a light shielding film formed on the phase shift film.

(Structure 10)

The mask blank according to structure 9, wherein the light shielding film is formed of a material containing chromium.

(Structure 11)

A transfer mask wherein the thin film of the mask blank according to any one of structures 1 to 8 is provided with a transfer pattern.

(Structure 12)

A transfer mask wherein the phase shift film of the mask blank according to structure 9 or 10 is provided with a transfer pattern and the light shielding film is provided with a pattern including a light shielding zone.

(Structure 13)

A method of manufacturing a semiconductor device, comprising a step of exposure-transferring a transfer pattern to a resist film on a semiconductor substrate by using the transfer mask according to structure 11 or 12.

### Effect of the Disclosure

According to this disclosure, it is possible to provide a mask blank considerably improved in lightfastness against exposure light having a wavelength of 200 nm or less.

By using the mask blank, it is possible to provide a transfer mask which is considerably improved in lightfastness against exposure light having a wavelength of 200 nm or less and which is stable in quality even after a long period of use.

Furthermore, by carrying out pattern transfer to a resist film on a semiconductor substrate by using the transfer mask, it is possible to manufacture a high-quality semiconductor device provided with a device pattern excellent in pattern accuracy.

### BRIEF DESCRIPTION OF THE DRAWINGS

FIG. 1 is a schematic sectional view of a mask blank according to one embodiment of this disclosure;

FIG. 2 is a schematic sectional view of a transfer mask according to one embodiment of this disclosure;

FIGS. 3A-3F are schematic sectional views for illustrating a manufacturing process of the transfer mask using the mask blank according to this disclosure;

FIG. 4 is a view for illustrating an in-depth distribution of a secondary ion intensity of silicon obtained by carrying out an analysis by secondary ion mass spectrometry on thin films (phase shift films) of mask blanks in Example 1 and Example 2 of this disclosure;

FIG. 5 is a view for illustrating a distribution of a secondary ion intensity of silicon in an internal region of the thin film (phase shift film) of the mask blank in Example 1 of this disclosure with respect to a depth from a film surface;

FIG. 6 is a view for illustrating a distribution of a secondary ion intensity of silicon in an internal region of the thin film (phase shift film) of the mask blank in Example 2 of this disclosure with respect to a depth from a film surface; and

FIG. 7 is a view for illustrating a distribution of a secondary ion intensity of silicon in an internal region of a thin film (phase shift film) of a mask blank in Comparative Example with respect to a depth from a film surface.

### MODE FOR EMBODYING THE DISCLOSURE

Now, a mode for embodying this disclosure will be described in detail with reference to the drawings.

The present inventors studied about a material containing no transition metal and containing silicon and nitrogen (hereinafter may be called a SiN-based material) as a material constituting a thin film for forming a transfer pattern. In addition, the present inventors studied, particularly focusing on analyzing a bonding state of silicon and nitrogen constituting the thin film. As a result, the present inventors reached a conclusion as follows. In order to solve the above-mentioned problems, it is preferable that, when a thin film formed of a material consisting of silicon and nitrogen or a material consisting of silicon, nitrogen, and one or more elements selected from metalloid elements and non-metal elements, is analyzed by secondary ion mass spectrometry to obtain an in-depth distribution of a secondary ion intensity of silicon, a slope of the secondary ion intensity [Counts/sec] of silicon with respect to a depth [nm] in a direction towards a transparent substrate is less than 150 [(Counts/sec)/nm] in an internal region of the thin film except a neighborhood region of the thin film near an interface with the transparent substrate and a surface region of the thin film that faces away from the transparent substrate. Thus, this disclosure has been completed.

Now, this disclosure will be described in detail on the basis of an embodiment.

A mask blank according to this disclosure comprises a transparent substrate on which a thin film of a SiN-based material for forming a transfer pattern is provided, and is applied to a phase shift mask blank, a binary mask blank, and other mask blanks for manufacturing various kinds of masks. In particular, the mask blank of this disclosure is preferably applied to the phase shift mask blank in that the effect of this disclosure, i.e., the effect of considerably improving lightfastness against short-wavelength exposure light such as an ArF excimer laser is fully exhibited. Therefore, description will hereinafter be made about a case where this disclosure is applied to the phase shift mask blank. As described above, however, this disclosure is not limited thereto.

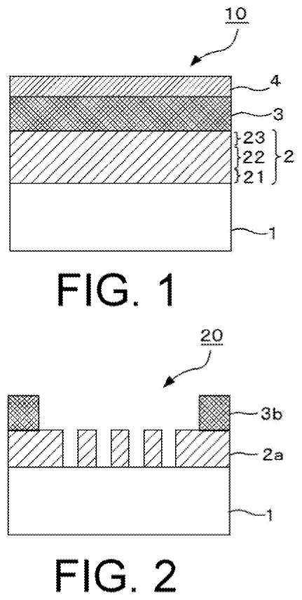

FIG. 1 is a schematic sectional view of a mask blank according to one embodiment of this disclosure.

As illustrated in FIG. 1, a mask blank 10 according to the one embodiment of this disclosure is a phase shift mask blank having a structure in which a phase shift film 2 as a thin film for forming a transfer pattern, a light shielding film 3 for forming a light shielding zone pattern or the like, and a hard mask film 4 are formed as layers in this order on a transparent substrate 1.

Herein, the transparent substrate 1 in the mask blank 10 is not particularly limited as far as it is a substrate for use in a transfer mask for manufacture of a semiconductor device. The transparent substrate is not particularly restricted as far as the substrate is transparent with respect to an exposure wavelength used in exposure transfer of a pattern onto a semiconductor substrate during manufacture of the semiconductor device. A synthetic quartz substrate and other various kinds of glass substrates (for example, soda lime glass, aluminosilicate glass, and so on) may be used. Among others, the synthetic quartz substrate is particularly preferably used because it is highly transparent with respect to an ArF excimer laser (wavelength: 193 nm) effective in fine pattern formation or in a region of a shorter wavelength than 193 nm.

In this disclosure, the phase shift film 2 is formed of a material containing no transition metal and containing silicon and nitrogen. Specifically, the phase shift film 2 is preferably formed of, for example, a material consisting of silicon and nitrogen or a material consisting of silicon, nitrogen, and one or more elements selected from metalloid elements and non-metal elements.

The phase shift film 2 may contain a metalloid element or elements in addition to silicon and nitrogen. As the metalloid element(s) in this case, it is preferable to contain, for example, one or more elements selected from boron, germanium, antimony, and tellurium because an increase in conductivity of silicon used as a sputtering target is expected.

The phase shift film 2 may contain a non-metal element or elements in addition to silicon and nitrogen. The non-metal elements in this case include narrow-sense non-metal elements (carbon, hydrogen, oxygen, phosphorus, sulfur, selenium, and so on), halogen (fluorine and so on), and noble gases (helium, argon, krypton, xenon, and so on). By appropriately selecting such non-metal elements and making those elements be contained, it is possible to adjust optical characteristics, film stress, a plasma etching rate, and the like of the phase shift film 2.

In this disclosure, a nitrogen content in the phase shift film 2 is preferably equal to 50 atomic % or more. A thin film of a SiN-based material with a less nitrogen content has a small refractive index n and a large extinction coefficient k with respect to, for example, exposure light of an ArF excimer laser (hereinafter may be called ArF exposure light). Furthermore, the thin film of the SiN-based material has a tendency to be increased in refractive index n and decreased in extinction coefficient k as the nitrogen content is increased. When the phase shift film 2 is attempted to be formed using the SiN-based material having a less nitrogen content, there arises a need to considerably increase a film thickness of the phase shift film 2 in order to assure a predetermined phase difference. This is because the SiN-based material has the small refractive index n. Furthermore, the SiN-based material with a less nitrogen content has a large extinction coefficient k. If the phase shift film 2 is formed with such a considerably large film thickness, the transmittance is excessively low so that a phase shift effect is difficult to be produced.

By making the SiN-based material with a less nitrogen content contain oxygen, the transmittance can be increased even with the same film thickness. However, when the SiN-based material with a less nitrogen content contains oxygen, the extinction coefficient k of the material is considerably lowered as compared with a case where nitrogen is contained whereas the refractive index n is not much increased as compared with the case where nitrogen is contained. Therefore, the film thickness can be reduced when the phase shift film 2 having a predetermined transmittance and a predetermined phase difference is formed by a material comprising the SiN-based material with a large amount of nitrogen contained therein. In particular, in case where the phase shift film 2 having a transmittance of 10% or more with respect to the ArF exposure light is formed of the SiN-based material, it is possible to assure the predetermined transmittance and the predetermined phase difference with a smaller film thickness.

The SiN-based material with a less nitrogen content is relatively low in lightfastness against exposure light having a wavelength of 200 nm or less because an abundance ratio of silicon unbonded to other elements is relatively high. When the nitrogen content of the phase shift film 2 is 50 atomic % or more, an abundance ratio of silicon bonded to other elements is increased so that the lightfastness against the exposure light having a wavelength of 200 nm or less can be increased. On the other hand, the nitrogen content in the phase shift film 2 is preferably 57 atomic % or less.

In particular, in a mask blank for use in manufacturing a halftone phase shift mask, in order to make a phase shift effect effectively function and to obtain a proper phase shift effect, the phase shift film 2 is required to have a function of transmitting exposure light of, for example, an ArF excimer laser (wavelength: 193 nm) at a transmittance of 1% or more and a function of causing the exposure light having been transmitted through the phase shift film 2 to have a phase difference of 150 degrees or more and 190 degrees or less with respect to exposure light transmitted through air for the same distance as a thickness of the phase shift film 2. The above-mentioned transmittance is preferably 2% or more, more preferably 10% or more, further preferably 15% or more. On the other hand, the transmittance is preferably adjusted to be 30% or less, more preferably 20% or less. As an exposure light irradiation method in a recent exposure apparatus, increasingly used is a type in which the exposure light is incident in a direction inclined by a predetermined angle with respect to an orthogonal direction to a film surface of the phase shift film 2. Therefore, the phase difference is preferably within the above-mentioned range.

The above-mentioned phase shift film 2 preferably has a film thickness of 90 nm or less. If the film thickness of the phase shift film 2 is greater than 90 nm, a bias (correction amount of a pattern line width or the like; hereinafter called an EMF bias) resulting from an electromagnetic field (EMF: Electromagnetic Field) effect is increased. In addition, a time required for EB (Electron Beam) defect correction becomes long. On the other hand, the film thickness of the phase shift film 2 is preferably 40 nm or more. If the film thickness is less than 40 nm, a predetermined exposure light transmittance and a predetermined phase difference required as the phase shift film may not be obtained.

In the mask blank according to this disclosure, it is important that, when the thin film (in this embodiment, the above-mentioned phase shift film 2) of the SiN-based material for forming the transfer pattern is analyzed by secondary ion mass spectrometry to obtain in-depth distribution of a secondary ion intensity of silicon, a slope of the secondary ion intensity [Counts/sec] of silicon with respect to a depth [nm] in a direction towards the transparent substrate is less than 150 [(Counts/sec)/nm] in an internal region of the thin film except a neighborhood region of the thin film near an interface with the transparent substrate and a surface region of the thin film that faces away from the transparent substrate.

The present inventors ascertained that, when the thin film of the SiN-based material, such as the above-mentioned phase shift film 2, is analyzed by secondary ion mass spectrometry (SIMS: Secondary Ion Mass Spectrometry) to obtain the in-depth distribution of the secondary ion intensity of silicon, the secondary ion intensity of silicon has a tendency to reach a peak in the surface region of the thin film, thereafter fall down once in the internal region, and gradually increase towards the transparent substrate (hereinafter may be abbreviated to “towards the substrate”). The present inventors also found out that the degree of increase (slope of increase) of the secondary ion intensity of silicon in the internal region is distinctively different depending on a strength of a bonding state of Si and N in the SiN-based material forming the thin film. The strength of the bonding state of Si and N in the SiN-based material is closely related to lightfastness of the thin film against the ArF exposure light.

As described above, when the thin film of the SiN-based material, such as the above-mentioned phase shift film 2, is analyzed by secondary ion mass spectrometry to obtain the in-depth distribution of the secondary ion intensity of silicon, the secondary ion intensity of silicon in the internal region of the thin film has a tendency to gradually increase towards the substrate. In addition, the degree of increase (slope of increase) of the secondary ion intensity of silicon in the internal region is distinctively different depending on the strength of the bonding state of Si and N in the SiN-based material forming the thin film. The reason has been examined and is assumed to be as follows.

In the secondary ion mass spectrometry, an acceleration voltage is applied to make primary ions, such as cesium ions, collide with a surface of a measured object and the number of secondary ions ejected from the surface of the measured object due to collision of the primary ions is measured. By continuously irradiating the SiN-based material film, poor in conductivity, with charged particles of the primary ions, charge-up is caused to occur and an electric field is then generated to move Si atoms towards the substrate. It is presumed that, because of the above, the secondary ion intensity of silicon is increased from the surface of the SiN-based material film towards the substrate. It is conceived that, in case of a film in which the bonding state of Si and N is strong in the internal region of the thin film, Si₃N₄ bonds high in bonding energy are relatively abundant and unbonded Si atoms are relatively scarce. It is presumed that, resulting from the above, the Si atoms tend to hardly move towards the substrate when the Si atoms are subjected to an influence of the electric field due to charge-up caused in the surface layer of the SiN-based material film by primary ion irradiation. It is conceived that, as a result thereof, the degree of increase (slope of increase) of the secondary ion intensity of silicon in the internal region of the thin film has a tendency to be relatively reduced. On the other hand, it is conceived that, in case of a film in which the bonding state of Si and N is weak in the internal region of the thin film, Si₃N₄ bonds high in bonding energy are relatively scarce and unbonded Si atoms are relatively abundant. Therefore, it is presumed that, when the Si atoms are subjected to the influence of the electric field due to charge-up caused in the surface layer of the SiN-based material film by primary ion irradiation, there is a tendency that the Si atoms easily move towards the substrate. It is conceived that, as a result thereof, the degree of increase (slope of increase) of the secondary ion intensity of silicon in the internal region of the thin film has a tendency to be relatively increased.

Based on the above-mentioned results, the present inventors further pursued diligent studies. As a result, it has been found important in fully exhibiting the effect of this disclosure that, when the thin film of the SiN-based material, such as the above-mentioned phase shift film 2, is analyzed by secondary ion mass spectrometry to obtain the in-depth distribution of the secondary ion intensity of silicon, the slope of the secondary ion intensity [Counts/sec] of silicon with respect to the depth [nm] in the direction towards the substrate is less than 150 [(Counts/sec)/nm] in the internal region of the thin film except the substrate neighborhood region and the surface region. It is supposed that, in the thin film mentioned above, the bonding state of Si and N in the internal region is strong, i.e., the abundance ratio of Si₃N₄ bonds high in bonding energy is large and the abundance ratio of unbonded Si atoms is small. Therefore, the lightfastness against the ArF exposure light is considerably improved in comparison with, for example, an existing MoSi-based thin film. On the other hand, it is supposed that, in case where the slope of the secondary ion intensity [Counts/sec] of silicon with respect to the depth [nm] in the direction towards the substrate is 150 [(Counts/sec)/nm] or more in the internal region of the above-mentioned thin film except the substrate neighborhood region and the surface region, such a thin film is weak in bonding state of Si and N in the internal region and the abundance ratio of Si₃N₄ bonds high in bonding energy is small whereas the abundance ratio of unbonded Si atoms is large. Therefore, an effect of improving the lightfastness against the ArF exposure light is small.

The bonding state of Si and N in the internal region of the thin film of the SiN-based material, such as the above-mentioned phase shift film 2, changes depending on a film-forming condition of the thin film (a sputtering method, a structure of a film-forming chamber, gases constituting a sputtering gas, a pressure in the film-forming chamber, a voltage applied to a target, and so on) or an annealing condition after film formation.

In this embodiment, the surface region mentioned above may be a region of the phase shift film 2 which extends over a range from a surface that faces away from the transparent substrate 1 to a depth of 10 nm towards the transparent substrate 1. The substrate neighborhood region may be a region of the phase shift film 2 which extends over a range from the interface with the transparent substrate 1 to a depth of 10 nm towards the surface region. In FIG. 1, the phase shift film 2 is illustrated as a substrate neighborhood region 21, an internal region 22, and a surface region 23. In this disclosure, the slope of the secondary ion intensity of silicon with respect to the depth in the direction towards the substrate is evaluated in the internal region of the thin film except the surface region and the substrate neighborhood region. This is because, in the surface region mentioned above, the secondary ion intensity of silicon is often subjected to an influence of surface oxidation of the thin film whereas, in the substrate neighborhood region mentioned above, the secondary ion intensity of silicon is often subjected to an influence of the transparent substrate. By eliminating those influences, it is possible to accurately evaluate the degree of increase (slope of increase) of the secondary ion intensity of silicon in the internal region of the thin film with respect to the depth in the direction towards the substrate.

Furthermore, the in-depth distribution of the secondary ion intensity of silicon obtained by analyzing the pattern-forming thin film (phase shift film 2 mentioned above) by secondary ion mass spectrometry is preferably obtained under measurement conditions that a primary ion species is Cs⁺, a primary accelerating voltage is 2.0 kV, and a primary ion irradiation region is an inside region of a square of 120 μm on a side. By evaluating, from the in-depth distribution of silicon obtained under the measurement conditions mentioned above, the slope of the secondary ion intensity of silicon in the internal region of the thin film with respect to the depth in the direction towards the substrate, it is possible to accurately determine whether or not the thin film is excellent in lightfastness against the ArF exposure light. Due to surface oxidation or the like, the surface region is greater in oxygen content than the internal region. The bonding state of Si and O is stronger than the bonding state of Si and N. Therefore, the surface region is higher in ArF lightfastness than the internal region.

Measurement of the secondary ion intensity of silicon for the pattern-forming thin film (above-mentioned phase shift film 2) is preferably carried out at measurement intervals of 2 nm or less in the depth direction, more preferably at measurement intervals of 1 nm or less. Furthermore, the slope of the secondary ion intensity [Counts/sec] of silicon in the internal region of the thin film except the substrate neighborhood region and the surface region with respect to the depth [nm] in the direction towards the substrate is preferably calculated by applying a least-square method (a model is a linear function) to measured values at all measuring points measured in the internal region at predetermined measurement intervals.

When the oxygen content is smaller in the internal region of the pattern-forming thin film (above-mentioned phase shift film 2), the total thickness of the thin film can be reduced. In the internal region, the oxygen content is preferably 10 atomic % or less, more preferably 5 atomic % or less, further preferably 1 atomic % or less, still further preferably equal to or less than a detection lower limit when the thin film is analyzed by X-ray photoelectron spectroscopy or the like. On the other hand, in the internal region of the pattern-forming thin film (above-mentioned phase shift film 2), the silicon content is preferably 40 atomic % or more, more preferably 43 atomic % or more. In the internal region, the silicon content is preferably 70 atomic % or less, more preferably 60 atomic % or less, further preferably 50 atomic % or less.

In the internal region of the pattern-forming thin film (phase shift film 2), the total content of non-metal elements except nitrogen and metalloid elements is preferably 10 atomic % or less, more preferably 5 atomic % or less, further preferably 1 atomic % or less, still further preferably equal to or less than a detection lower limit when the thin film is analyzed by X-ray photoelectron spectroscopy. In the internal region of the pattern-forming thin film (above-mentioned phase shift film 2), a difference in content of each element constituting the internal region in a film thickness direction is preferably 10 atomic % or less, more preferably 8 atomic % or less, further preferably 5 atomic % or less. Furthermore, in a region of the pattern-forming thin film, including the internal region and the substrate neighborhood region (i.e., a region of the thin film except the surface region), a difference in content of each element constituting the region in the film thickness direction is preferably 10 atomic % or less, more preferably 8 atomic % or less, further preferably 5 atomic % or less.

On the other hand, an upper layer film may be formed on the thin film. In this case, a layered structure of the thin film and the upper layer film constitutes the pattern-forming thin film. On the other hand, a lower layer film may be formed under the thin film. In this case, a layered structure of the thin film and the lower layer film constitutes the pattern-forming thin film. Furthermore, a layered structure of the lower layer film, the thin film, and the upper layer film may constitute the pattern-forming thin film. The lower layer film and the upper layer film are preferably formed of a material consisting of silicon and oxygen, or a material consisting of silicon, oxygen, and one or more elements selected from metalloid elements and non-metal elements. In this case, in the lower layer film and the upper layer film, the oxygen content is preferably 40 atomic % or more, more preferably 50 atomic % or more, further preferably 60 atomic % or more.

The lower layer film and the upper layer film are preferably formed of a material consisting of silicon, nitrogen, and oxygen, or a material consisting of silicon, nitrogen, oxygen, and one or more elements selected from metalloid elements and non-metal elements. In the lower layer film and the upper layer film, the total content of nitrogen and oxygen is preferably 40 atomic % or more, more preferably 50 atomic % or more, further preferably 55 atomic % or more. The lower layer film and the upper layer film formed of the above-mentioned material internally contain a large amount of Si and O in the bonding state. Therefore, the lower layer film and the upper layer film are high in ArF lightfastness than the above-mentioned thin film.

Next, the above-mentioned light shielding film 3 will be described. In this embodiment, the above-mentioned light shielding film 3 is provided for the purpose of forming a light shielding pattern such as a light shielding zone and the purpose of forming various types of marks such as alignment marks. The light shielding film 3 also has a function of transferring a pattern of the hard mask film 4 to the phase shift film 2 as faithfully as possible. The light shielding film 3 is formed of a material containing chromium in order to assure etching selectivity with respect to the phase shift film 2 formed of the SiN-based material.

The material containing chromium may be, for example, elemental chromium (Cr), or a chromium compound containing chromium with an element or elements, such as oxygen, nitrogen, and carbon, added thereto (for example, CrN, CrC, CrO, CrON, CrCN, CrOC, CrOCN, and so on).

A method of forming the light shielding film 3 is not particularly limited. Among others, sputtering film formation is preferable. The sputtering film formation is suitable because a uniform film with a constant film thickness can be formed.

The light shielding film 3 may have a single layer structure or a layered structure. For example, the light shielding film may have a double layer structure comprising a light shielding layer and a surface reflection prevention layer, or a three layer structure further comprising a back surface reflection prevention layer.

The light shielding film 3 is required to secure predetermined light shieldability. In this embodiment, a layered structure comprising the phase shift film 2 and the light shielding film 3 preferably has an optical density (OD) of 2.8 or more, preferably 3.0 or more, for example, with respect to exposure light of an ArF excimer laser (wavelength: 193 nm) effective for fine pattern formation.

The film thickness of the light shielding film 3 is not particularly limited but is preferably 80 nm or less, more preferably 70 nm or less, in order to accurately form a fine pattern. On the other hand, since the light shielding film 3 is required to secure predetermined light shieldability (optical density) as described above, the film thickness of the light shielding film 3 is preferably 30 nm or more, more preferably 40 nm or more.

The hard mask film 4 is required to be formed of a material having high etching selectivity with respect to the light shielding film 3 directly thereunder. In this embodiment, by selecting, for example, a material containing silicon as the material of the hard mask film 4, it is possible to secure high etching selectivity with respect to the light shielding film 3 formed of the material containing chromium. Accordingly, it is possible not only to achieve thinning of a resist pattern formed on a surface of the mask blank 10 but also to reduce the film thickness of the hard mask film 4. Therefore, the resist pattern formed on the surface of the mask blank 10 and comprising a fine transfer pattern can be accurately transferred to the hard mask film 4.

The material containing silicon and forming the hard mask film 4 may be a material containing silicon and one or more elements selected from oxygen, nitrogen, carbon, boron, and hydrogen. Other materials containing silicon and suitable for the hard mask film 4 may be a material containing, in addition to silicon and transition metal, one or more elements selected from oxygen, nitrogen, carbon, boron, and hydrogen. The transition metal in this case may be, for example, molybdenum (Mo), tungsten (W), titanium (Ti), tantalum (Ta), zirconium (Zr), hafnium (Hf), niobium (Nb), vanadium (V), cobalt (Co), nickel (Ni), ruthenium (Ru), tin (Sn), chromium (Cr), and so on.

The hard mask film 4 formed of a material containing silicon and oxygen has a tendency to be low in adhesion with a resist film of an organic material. Therefore, it is preferable to carry out HMDS (Hexamethyl disilazane) treatment on a surface of the hard mask film 4 so as to improve surface adhesion.

A method of forming the hard mask film 4 need not particularly be limited. Among others, sputtering film formation is preferable. The sputtering film formation is suitable because a uniform film with a constant thickness can be formed.

The film thickness of the hard mask film 4 need not particularly be limited. However, the hard mask film 4 serves as an etching mask when the light shielding film 3 directly thereunder is patterned and, therefore, is required to have a film thickness at least to the extent that the hard mask film does not disappear before completion of etching of the light shielding film 3 directly thereunder. On the other hand, if the film thickness of the hard mask film 4 is large, it is difficult to thin the resist pattern directly thereon. From this point of view, the film thickness of the hard mask film 4 is preferably within a range of, for example, 2 nm or more and 15 nm or less, more preferably 3 nm or more and 10 nm or less.

The hard mask film 4 may be omitted. However, in order to realize thinning of the resist pattern, it is desirable to adopt the structure provided with the hard mask film 4 as in this embodiment.

On the other hand, the light shielding film 3 may be formed of a material containing silicon, a material containing transition metal and silicon, or a material containing tantalum. In this case, it is difficult to secure etching selectivity between the phase shift film 2 and the light shielding film 3. Therefore, an etching stopper film is preferably formed between the phase shift film 2 and the light shielding film 3. The etching stopper film in this case is preferably formed of a material containing chromium but may be formed of a material containing silicon with an oxygen content of 50 atomic % or more. A mask blank having such a structure comprising the etching stopper film between the phase shift film 2 and the light shielding film 3 is included in the mask blank of this disclosure.

Although the mask blank 10 having the structure without another film provided between the transparent substrate 1 and the phase shift film 2 has been described, the mask blank of this disclosure is not limited thereto. For example, a mask blank having a structure comprising an etching stopper film between the transparent substrate 1 and the phase shift film 2 is also included in the mask blank of this disclosure. The etching stopper film in this case is preferably formed of a material containing chromium, a material containing aluminum and oxygen, or a material containing aluminum, oxygen, and silicon.

A mask blank having a configuration comprising a resist film formed on the surface of the mask blank 10 is also included in the mask blank of this disclosure.

In the mask blank 10 having the above-described structure according to the embodiment of this disclosure, when the thin film (in this embodiment, the above-mentioned phase shift film 2) of the SiN-based material for forming the transfer pattern is analyzed by secondary ion mass spectrometry to obtain the in-depth distribution of the secondary ion intensity of silicon, the slope of the secondary ion intensity [Counts/sec] of silicon with respect to the depth [nm] in the direction towards the transparent substrate is less than 150 [(Counts/sec)/nm] in the internal region of the thin film except the substrate neighborhood region and the surface region. In the thin film mentioned above, the bonding state of Si and N in the internal region is strong so that the lightfastness against the exposure light having a wavelength of 200 nm or less, such as the ArF excimer laser, is considerably improved as compared with, for example, the existing MoSi-based thin film. Therefore, by using the mask blank of this disclosure, it is possible to considerably improve the lightfastness against the exposure light having a wavelength of 200 nm or less, such as the ArF excimer laser or the like, and to obtain a transfer mask stable in quality even after a long period of use.

This disclosure also provides the transfer mask manufactured from the above-mentioned mask blank according to this disclosure.

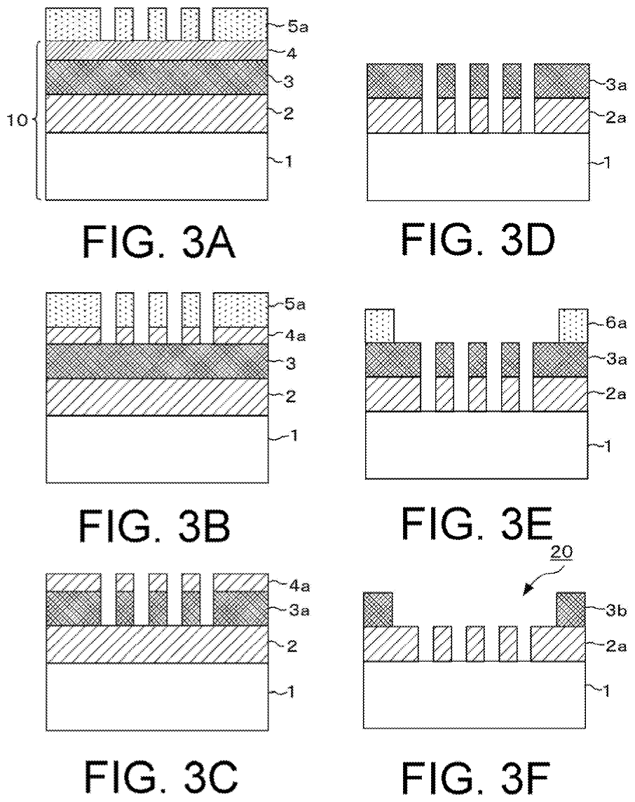

FIG. 2 is a schematic sectional view of the transfer mask according to one embodiment of this disclosure. FIGS. 3A-3F are schematic sectional views for illustrating a manufacturing process of the transfer mask using the mask blank according to this disclosure.

In a transfer mask 20 (phase shift mask) of the one embodiment illustrated in FIG. 2, the phase shift film 2 of the mask blank 10 is provided with a phase shift film pattern 2a (transfer pattern) and the light shielding film 3 of the mask blank 10 is provided with a light shielding film pattern 3b (a pattern including a light shielding zone).

Next referring to FIGS. 3A-3F, description will be made of a method for manufacturing the transfer mask using the mask blank according to this disclosure.

On the surface of the mask blank 10, a resist film for electron beam writing is formed by spin coating to a predetermined thickness. A predetermined pattern is written on the resist film by electron beam writing and, after writing, developed to thereby form a predetermined resist pattern 5a (see FIG. 3A). The resist pattern 5a has a desired device pattern to be formed on the phase shift film 2 and to serve as a final transfer pattern.

Next, by dry etching using, as a mask, the resist pattern 5a formed on the hard mask film 4 of the mask blank 10 and using a fluorine-based gas, a hard mask pattern 4a is formed on the hard mask film 4 (see FIG. 3B). In this embodiment, the hard mask film 4 is formed of a material containing silicon.

Next, after removing the remaining resist pattern 5a, a light shielding film pattern 3a corresponding to a pattern to be formed on the phase shift film 2 is formed on the light shielding film 3 by dry etching using, as a mask, the pattern 4a formed on the hard mask film 4 and using a gaseous mixture of a chlorine-based gas and an oxygen gas (see FIG. 3C). In this embodiment, the light shielding film 3 is formed of a material containing chromium.

Next, by dry etching using, as a mask, the pattern 3a formed on the light shielding film 3 and using a fluorine-based gas, the phase shift film pattern (transfer pattern) 2a is formed on the phase shift film 2 formed of a SiN-based material (see FIG. 3D). In the dry etching process of the phase shift film 2, the hard mask film pattern 4a exposed on a surface is removed.

Next, a resist film similar to that mentioned above is formed by spin coating on an entire surface of the substrate in the above-mentioned state illustrated in FIG. 3D. A predetermined pattern (for example, a pattern corresponding to a light shielding zone pattern) is written on the resist film by electron beam writing and, after writing, developed to thereby form a predetermined resist pattern 6a (see FIG. 3E).

Subsequently, by dry etching using the resist pattern 6a as a mask and using a gaseous mixture of a chlorine-based gas and an oxygen gas, the exposed light shielding film pattern 3a is etched to remove, for example, the light shielding film pattern 3a in a transfer pattern forming region and to form the light shielding zone pattern 3b in a peripheral part around the transfer pattern forming region. Finally, the remaining resist pattern 6a is removed to complete the transfer mask (phase shift mask) 20 in which the fine pattern 2a of the phase shift film is formed on the transparent substrate 1 to serve as the transfer pattern (see FIG. 3F).

As described above, by using the mask blank of this disclosure, it is possible to obtain the transfer mask which is considerably improved in lightfastness against the exposure light having a wavelength of 200 nm or less, such as the ArF excimer laser, and which is stable in quality even after a long period of use.

Furthermore, according to the method for manufacturing a semiconductor device, which includes a step of exposure-transferring the transfer pattern of the transfer mask to the resist film on the semiconductor substrate by lithography using the transfer mask 20 manufactured using the mask blank of this disclosure and stable in quality even after a long period of use, it is possible to manufacture a high-quality semiconductor device provided with a device pattern excellent in pattern accuracy.

### EXAMPLES

Hereinafter, the embodiment of this disclosure will be described more specifically with reference to examples.

### Example 1

Example 1 relates to a mask blank for use in manufacture of a transfer mask (phase shift mask) using an ArF excimer laser having a wavelength of 193 nm as exposure light, and to manufacture of the transfer mask.

A mask blank 10 used in Example 1 has a structure in which a phase shift film 2, a light shielding film 3, and a hard mask film 4 are formed as layers on a transparent substrate 1 in this order, as illustrated in FIG. 1. The mask blank 10 was manufactured in the following manner.

The transparent substrate 1 (about 152 mm×152 mm in size×about 6.35 mm in thickness) made of synthetic quartz glass was prepared. In the transparent substrate 1, main surfaces and an end face are polished to a predetermined surface roughness (for example, the main surface has a root mean square roughness Rq of 0.2 nm or less).

Next, the transparent substrate 1 was placed in a single-wafer RF sputtering apparatus. Using a silicon (Si) target and a gaseous mixture of krypton (Kr), helium (He), and nitrogen (N₂) as a sputtering gas (flow rate ratio Kr:He:N₂=3:16:4, pressure=0.24 Pa) with an electric power of an RF power supply set at 1.5 kW, reactive sputtering (RF sputtering) was carried out to form the phase shift film 2 consisting of silicon and nitrogen (Si:N=46.9 atomic %:53.1 atomic %) on the transparent substrate 1 to a thickness of 62 nm. Herein, the composition of the phase shift film 2 is a result obtained by measurement by X-ray photoelectron spectroscopy (XPS) for a phase shift film formed on another transparent substrate under the conditions same as those mentioned above.

Next, the transparent substrate 1 provided with the phase shift film 2 was placed in an electric furnace and subjected to heat treatment in air under the conditions of a heating temperature of 550° C. and a treatment time (1 hour). The electric furnace similar in structure to a vertical furnace disclosed in FIG. 5 of JP 2002-162726 A was used. The heat treatment in the electric furnace was carried out in a state where air was introduced into the furnace through a chemical filter. After the heat treatment in the electric furnace, a refrigerant was injected into the electric furnace to perform forced cooling on the transparent substrate to a predetermined temperature (around 250° C.). The forced cooling was carried out in a state where a nitrogen gas as the refrigerant was introduced into the furnace (substantially in a nitrogen gas atmosphere). After the forced cooling, the transparent substrate was taken out from the electric furnace and natural cooling was carried out in air down to ordinary temperature (25° C. or lower).

For the phase shift film 2 after the heat treatment and the cooling mentioned above, a transmittance and a phase difference with respect to the ArF excimer laser light (wavelength: 193 nm) were measured by a phase shift amount measurement apparatus (MPM-193 manufactured by Lasertec Corporation). As a result, the transmittance was 18.6% and the phase difference was 177.1 degrees.

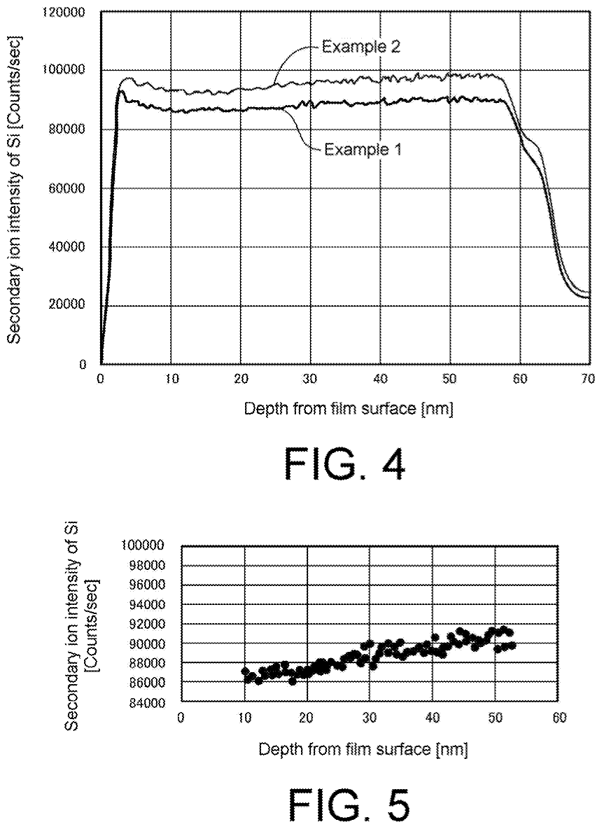

Next, for the phase shift film 2 after the heat treatment and the cooling mentioned above, analysis of in-depth distribution of a secondary ion intensity of silicon was carried out by secondary ion mass spectrometry. The analysis was carried out by using a quadrupole secondary ion mass spectrometer (PHI ADEPT1010 manufactured by ULVAC-PHI, Incorporated) as an analyzer and under measurement conditions that a primary ion species is Cs⁺, a primary accelerating voltage is 2.0 kV, and a primary ion irradiation region is an inside region of a square of 120 μm on a side. Measurement of the secondary ion intensity of silicon for the phase shift film 2 in Example 1 was carried out at measurement intervals of 0.54 nm on average in a depth direction. FIG. 4 shows the in-depth distribution of the secondary ion intensity of silicon in the phase shift film 2 of Example 1, which was obtained as a result of the analysis. A thick line in FIG. 4 represents the result of Example 1.

From the result in FIG. 4, it is understood that, in the phase shift film 2 of Example 1, the secondary ion intensity of silicon has a tendency to reach a peak in a region from the surface of the phase shift film 2 to a depth of 10 nm (surface region), thereafter fall down once, and gradually increase therefrom towards the transparent substrate in a subsequent internal region and that the secondary ion intensity considerably decreases in a region (substrate neighborhood region) extending over a range of 10 nm from the interface with the transparent substrate towards the surface region.

FIG. 5 represents a result of plotting, from the result of the in-depth distribution of the secondary ion intensity of silicon in the phase shift film 2 in Example 1 illustrated in FIG. 4, distribution of the secondary ion intensity of silicon with respect to a depth from the film surface at a plurality of positions in the internal region of the phase shift film 2 except the surface region and the substrate neighborhood region.

From the result illustrated in FIG. 5, a degree of increase (slope of increase) of the secondary ion intensity [Counts/sec] of silicon in the internal region of the phase shift film 2 with respect to a depth [nm] in the direction towards the transparent substrate was calculated by applying the least-square method (a model is a linear function). As a result, the degree was 105.3 [(Count/sec)/nm].

Next, the phase shift film 2 of Example 1 was formed on another transparent substrate 1. In the manner similar to that mentioned above, heat treatment, forced cooling, and natural cooling were carried out. The phase shift film 2 after the heat treatment and the cooling had a transmittance of 18.6% and a phase difference of 177.1 degrees with respect to the ArF excimer laser light (wavelength: 193 nm).

Subsequently, the transparent substrate 1 provided with the phase shift film 2 was placed in a single-wafer DC sputtering apparatus and the light shielding film 3 of a chromium-based material and having a single layer structure was formed on the phase shift film 2. Using a target of chromium and a gaseous mixture of Argon (Ar), carbon dioxide (CO₂), and helium (He) (flow rate ratio Ar:CO₂:He=18:33:28, pressure=0.15 Pa) as a sputtering gas with an electric power of a DC power supply set at 1.8 kW, reactive sputtering (DC sputtering) was carried out to form, on the phase shift film 2, the light shielding film 3 comprising a CrOC film containing chromium, oxygen, and carbon to a thickness of 56 nm.

A layered structure of the phase shift film 2 and the light shielding film 3 had an optical density of 3.0 or more at the wavelength (193 nm) of the ArF excimer laser.

Furthermore, the transparent substrate 1 with the phase shift film 2 and the light shielding film 3 formed as layers was placed in a single-wafer sputtering apparatus. By reactive sputtering (RF sputtering) using a silicon dioxide (SiO₂) target and an argon gas (pressure=0.03 Pa) as a sputtering gas with an electric power of an RF power supply set at 1.5 kW, the hard mask film 4 consisting of silicon and oxygen was formed on the light shielding film 3 to a thickness of 5 nm.

As described above, the mask blank 10 of Example 1 was manufactured in which the phase shift film 2, the light shielding film 3, and the hard mask film 4 were formed as layers on the transparent substrate 1 in this order.

Next, using the mask blank 10, the transfer mask (phase shift mask) was manufactured according to the above-mentioned manufacturing process illustrated in FIGS. 3A-3F. The reference numerals in the following correspond to the reference numerals in FIGS. 3A-3F.

At first, an upper surface of the mask blank 10 was subjected to HMDS treatment. Thereafter, a chemically amplified resist for electron beam writing (PRL009 manufactured by Fuji Film Electronics Materials Co. Ltd.) was applied by spin coating and subjected to predetermined baking to form a resist film having a film thickness of 80 nm. Using an electron beam writing apparatus, a predetermined device pattern (a pattern corresponding to a transfer pattern to be formed on the phase shift film 2) was written on the resist film and, thereafter, the resist film was developed to form a resist pattern 5a (see FIG. 3A).

Next, dry etching of the hard mask film 4 was carried out with the resist pattern 5a used as a mask to form a pattern 4a on the hard mask film 4 (see FIG. 3B). As a dry etching gas, a fluorine-based gas (CF₄) was used.

Next, after the remaining resist pattern 5a was removed, the light shielding film 3 formed of a chromium-based material and having a single layer structure was dry etched with the pattern 4a of the hard mask film used as a mask to form a pattern 3a on the light shielding film 3 (see FIG. 3C). As a dry etching gas, a gaseous mixture (Cl₂:O₂=15:1 (flow rate ratio)) of a chlorine gas (Cl₂) and an oxygen gas (O₂) was used.

Next, using, as a mask, the pattern 3a formed on the light shielding film 3, the phase shift mask 2 was dry etched to form a phase shift film pattern (transfer pattern) 2a on the phase shift film 2 (see FIG. 3D). As a dry etching gas, a fluorine-based gas (gaseous mixture of SF₆ and He) was used. In the dry etching process of the phase shift film 2, the hard mask film pattern 4a exposed on a surface was removed.

Next, a resist film similar to that mentioned above was formed by spin coating on an entire surface of the substrate in the state illustrated in FIG. 3D). A predetermined pattern (a pattern corresponding to a light shielding zone pattern) was written on the resist film by electron beam writing and, after writing, developed to thereby form a predetermined resist pattern 6a (see FIG. 3E).

Subsequently, by dry etching using the resist pattern 6a as a mask and using a gaseous mixture (Cl₂:O₂: 4:1 (flow rate ratio)) of a chlorine gas and an oxygen gas, the exposed light shielding film pattern 3a was etched to remove, for example, the light shielding film pattern 3a in a transfer pattern forming region and to form a light shielding zone pattern 3b in a peripheral part around the transfer pattern forming region.

Finally, the remaining resist pattern 6a was removed to manufacture the transfer mask (phase shift mask) 20 in which the fine pattern 2a of the phase shift film is formed on the transparent substrate 1 to serve as the transfer pattern (see FIG. 3F).

The exposure light transmittance and the phase difference of the phase shift film pattern 2a were not changed from those at the time of manufacture of the mask blank.

The above-mentioned transfer mask 20 thus obtained was subjected to inspection of a mask pattern by a mask inspection apparatus. As a result, it was confirmed that a fine pattern was formed in an allowable range from a designed value.

In the transfer mask 20 thus obtained, an area of the phase shift film pattern 2a where the light shielding zone pattern 3b was not formed as a layer was subjected to intermittent irradiation with the ArF excimer laser light so that a cumulative irradiation amount was equal to 40 kJ/cm². The cumulative irradiation amount of 40 kJ/cm² corresponds to about 100,000 times of use of the transfer mask.

The transmittance and the phase difference of the phase shift film pattern 2a after the above-mentioned irradiation were measured. As a result, for the ArF excimer laser light (wavelength: 193 nm), the transmittance was 20.1% and the phase difference was 174.6 degrees. Therefore, variation amounts before and after the irradiation were +1.5% for the transmittance and −2.5 degrees for the phase difference. Thus, the variation amounts were suppressed to be very small and the variation amounts of such levels do not affect mask performance at all. Variation (CD variation) in line width of the phase shift film pattern 2a before and after the irradiation was also suppressed to 2 nm or less.

From the foregoing, it is understood that, in the mask blank of Example 1, when the thin film (phase shift film) of a SiN-based material is analyzed by secondary ion mass spectrometry to obtain the in-depth distribution of the secondary ion intensity of silicon, the slope of the secondary ion intensity [Counts/sec] of silicon with respect to the depth [nm] in the direction towards the transparent substrate is less than 150 [(Counts/sec)/nm] in the internal region of the thin film except the substrate neighborhood region and the surface region and that, by such a structure, the thin film (phase shift film) is considerably improved in lightfastness against cumulative irradiation with exposure light having a short wavelength of 200 nm or less, such as an ArF excimer laser, and the mask blank has extremely high lightfastness. By using the mask blank of Example 1, it is possible to obtain the transfer mask (phase shift mask) which is considerably improved in lightfastness against the exposure light having a wavelength of 200 nm or less, such as the ArF excimer laser, and which is stable in quality even after a long period of use.

Furthermore, for the transfer mask 20 after the cumulative irradiation with the ArF excimer laser light, simulation was carried out by using AIMS193 (manufactured by Carl Zeiss) to obtain an exposure transfer image at the time of carrying out exposure transfer onto a resist film on a semiconductor device using exposure light having a wavelength of 193 nm. When the exposure transfer image obtained by the simulation was examined, a design specification was sufficiently satisfied. From the above, it is said that, when the transfer mask 20 manufactured from the mask blank of Example 1 is set in the exposure apparatus and exposure transfer is carried out by the exposure light of the ArF excimer laser until the cumulative irradiation amount reaches, for example, 40 kJ/cm², exposure transfer can be carried out with high accuracy onto the resist film on the semiconductor device.

### Example 2

A mask blank 10 used in Example 2 was manufactured in the following manner.

A transparent substrate 1 (about 152 mm×152 mm in size×about 6.35 mm in thickness) made of synthetic quartz glass and same as that used in Example 1 was prepared.

Next, the transparent substrate 1 was placed in a single-wafer RF sputtering apparatus. Using a silicon (Si) target and a gaseous mixture of krypton (Kr), helium (He), and nitrogen (N₂) as a sputtering gas (flow rate ratio Kr:He:N₂=3:16:4, pressure=0.24 Pa) with an electric power of an RF power supply set at 1.5 kW, reactive sputtering (RF sputtering) was carried out to form a phase shift film 2 consisting of silicon and nitrogen (Si:N=46.9 atomic %:53.1 atomic %) on the transparent substrate 1 to a thickness of 62 nm. Herein, the composition of the phase shift film 2 is a result obtained by measurement by X-ray photoelectron spectroscopy (XPS) for a phase shift film formed on another transparent substrate under the conditions same as those mentioned above.

Next, the transparent substrate 1 provided with the phase shift film 2 was placed on a hot plate and subjected to first heat treatment in air under the conditions of a heating temperature of 280° C. and a treatment time of 5 minutes. After the first heat treatment, the above-mentioned substrate was placed in an electric furnace and subjected to second heat treatment in air under the conditions of a heating temperature of 550° C. and a treatment time (1 hour). The electric furnace similar in structure to that in Example 1 was used. The heat treatment in the electric furnace was carried out in a state where air was introduced into the furnace through a chemical filter. After the heat treatment in the electric furnace, a refrigerant was injected into the electric furnace to perform forced cooling on the substrate to a predetermined temperature (around 250° C.). The forced cooling was carried out in a state where a nitrogen gas as the refrigerant was introduced into the furnace (substantially in a nitrogen gas atmosphere). After the forced cooling, the substrate was taken out from the electric furnace and natural cooling was carried out in air down to ordinary temperature (25° C. or less).

For the phase shift film 2 after the first and the second heat treatments and the cooling mentioned above, a transmittance and a phase difference with respect to ArF excimer laser light (wavelength: 193 nm) were measured by a phase shift amount measurement apparatus (MPM-193 manufactured by Lasertec Corporation). As a result, the transmittance was 18.6% and the phase difference was 177.1 degrees.

Next, for the phase shift film 2 after the first and the second heat treatments and the cooling mentioned above, analysis of in-depth distribution of a secondary ion intensity of silicon was carried out by secondary ion mass spectrometry in the manner similar to Example 1. The measurement conditions are similar to those in Example 1. Measurement of the secondary ion intensity of silicon for the phase shift film 2 in Example 2 was carried out at measurement intervals of 0.54 nm on average in a depth direction. FIG. 4 shows an in-depth distribution of the secondary ion intensity of silicon in the phase shift film 2 of Example 2, which was obtained as a result of the analysis. A narrow line in FIG. 4 represents the result of Example 2.

From the result in FIG. 4, it is understood that, in the phase shift film 2 of Example 2, the secondary ion intensity of silicon has a tendency to reach a peak in a region (surface region) from a surface of the phase shift film 2 to a depth of 10 nm, thereafter fall down once, and gradually increase therefrom towards the transparent substrate in a subsequent internal region and that the secondary ion intensity considerably decreases in a region (substrate neighborhood region) extending over a range of 10 nm from the interface with the transparent substrate towards the surface region. This tendency is substantially same as that in Example 1. However, the degree (slope) of increase of the secondary ion intensity in the internal region towards the transparent substrate is slightly greater in Example 2 than in Example 1.

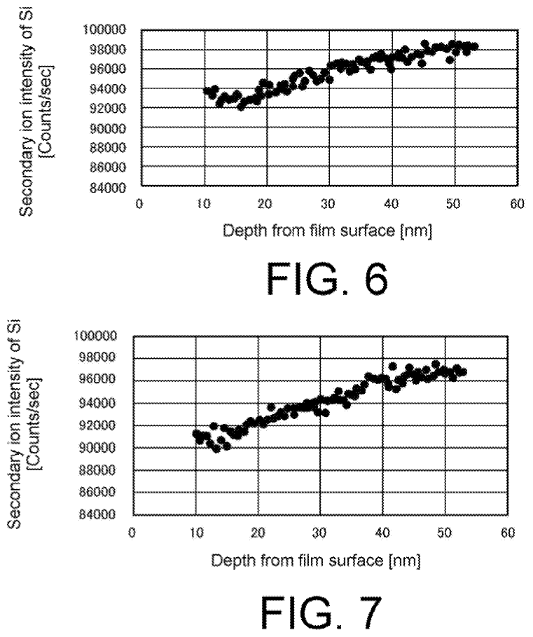

FIG. 6 represents a result of plotting, from the result of the in-depth distribution of the secondary ion intensity of silicon in the phase shift film 2 in Example 2 illustrated in FIG. 4, distribution of the secondary ion intensity of silicon with respect to a depth from a film surface at a plurality of positions in the internal region of the phase shift film 2 except the surface region and the substrate neighborhood region.

From the result illustrated in FIG. 6, a degree of increase (slope of increase) of the secondary ion intensity [Counts/sec] of silicon in the internal region of the phase shift film 2 with respect to a depth [nm] in a direction towards the transparent substrate was calculated by applying the least-square method (a model is a linear function). As a result, the degree was 145.7 [(Count/sec)/nm].

Next, the phase shift film 2 of Example 2 was formed on another transparent substrate 1. In the manner similar to that mentioned above, first and second heat treatments, forced cooling, and natural cooling were carried out. The phase shift film 2 after the heat treatments and the cooling had a transmittance of 18.6% and a phase difference of 177.1 degrees with respect to the ArF excimer laser light (wavelength: 193 nm), which were same as those mentioned above.

Subsequently, the transparent substrate 1 provided with the phase shift film 2 was placed in a single-wafer DC sputtering apparatus and a light shielding film 3 of a chromium-based material having a single layer structure, which is similar to that in Example 1, was formed on the phase shift film 2. Specifically, the light shielding film 3 comprising a CrOC film and having a single layer structure was formed to a thickness of 56 nm.

A layered structure of the phase shift film 2 and the light shielding film 3 had an optical density of 3.0 or more at the wavelength (193 nm) of the ArF excimer laser.

Furthermore, the transparent substrate 1 with the phase shift film 2 and the light shielding film 3 formed as layers was placed in a single-wafer sputtering apparatus and a hard mask film 4 consisting of silicon and oxygen similar to that in Example 1 was formed on the light shielding film 3 to a thickness of 5 nm.

As described above, the mask blank 10 in Example 2 was manufactured in which the phase shift film 2, the light shielding film 3, and the hard mask film 4 were formed as layers on the transparent substrate 1 in this order.

Next, using the mask blank 10, a transfer mask (phase shift mask) 20, in which a fine pattern 2a of the phase shift film to serve as a transfer pattern was provided on the transparent substrate 1, was manufactured according to the above-mentioned manufacturing process illustrated in FIGS. 3A-3F and in the manner similar to Example 1 mentioned above.

The exposure light transmittance and the phase difference of the phase shift film pattern 2a were not changed from those at the time of manufacture of the mask blank.

The above-mentioned transfer mask 20 thus obtained was subjected to inspection of a mask pattern by a mask inspection apparatus. As a result, it was confirmed that a fine pattern was formed in an allowable range from a designed value.

In the transfer mask 20 thus obtained, an area of the phase shift film pattern 2a where a light shielding zone pattern 3b was not formed as a layer was subjected to intermittent irradiation with the ArF excimer laser light so that a cumulative irradiation amount was equal to 40 kJ/cm².

The transmittance and the phase difference of the phase shift film pattern 2a after the above-mentioned irradiation were measured. As a result, for the ArF excimer laser light (wavelength: 193 nm), the transmittance was 20.8% and the phase difference was 173.4 degrees. Therefore, variation amounts before and after the irradiation were +2.2% for the transmittance and −3.7 degrees for the phase difference. Thus, the variation amounts were suppressed to be very small and the variation amounts of such levels do not affect mask performance at all. Variation (CD variation) in line width of the phase shift film pattern 2a before and after the irradiation was also suppressed to 3 nm or less.

From the foregoing, it is understood that, in the mask blank of Example 2, when the thin film (phase shift film) of a SiN-based material is analyzed by secondary ion mass spectrometry to obtain the in-depth distribution of the secondary ion intensity of silicon, the slope of the secondary ion intensity [Counts/sec] of silicon with respect to the depth [nm] in the direction towards the transparent substrate is less than 150 [(Counts/sec)/nm] in the internal region of the thin film except the substrate neighborhood region and the surface region and that, by such a structure, the thin film (phase shift film) is considerably improved in lightfastness against cumulative irradiation with the exposure light having a short wavelength of 200 nm or less such as an ArF excimer laser, and the mask blank has extremely high lightfastness. By using the mask blank of Example 2, it is possible to obtain the transfer mask (phase shift mask) which is considerably improved in lightfastness against the exposure light having a wavelength of 200 nm or less, such as the ArF excimer laser, and which is stable in quality even after a long period of use.

Furthermore, for the transfer mask 20 after the cumulative irradiation with the ArF excimer laser light, simulation was carried out by using AIMS193 (manufactured by Carl Zeiss) to obtain an exposure transfer image at the time of carrying out exposure transfer onto a resist film on a semiconductor device using exposure light having a wavelength of 193 nm. When the exposure transfer image obtained by the simulation was examined, a design specification was sufficiently satisfied. From the above, it is said that, when the transfer mask 20 manufactured from the mask blank of Example 2 is set in the exposure apparatus and exposure transfer is carried out by the exposure light of the ArF excimer laser until the cumulative irradiation amount reaches, for example, 40 kJ/cm², exposure transfer can be carried out with high accuracy onto the resist film on the semiconductor device.

### COMPARATIVE EXAMPLE

A mask blank 10 used in Comparative Example was manufactured in the following manner.

A transparent substrate 1 (about 152 mm×152 mm in size×about 6.35 mm in thickness) made of synthetic quartz glass and same as that used in Example 1 was prepared.

Next, the transparent substrate 1 was placed in a single-wafer RF sputtering apparatus. Using a silicon (Si) target and a gaseous mixture of krypton (Kr), helium (He), and nitrogen (N₂) as a sputtering gas (flow rate ratio Kr:He:N₂=3:16:4, pressure=0.24 Pa) with an electric power of an RF power supply set at 1.5 kW, reactive sputtering (RF sputtering) was carried out to form a phase shift film 2 consisting of silicon and nitrogen (Si:N=46.9 atomic %:53.1 atomic %) on the transparent substrate 1 to a thickness of 62 nm. Herein, the composition of the phase shift film 2 is a result obtained by measurement by X-ray photoelectron spectroscopy (XPS) for a phase shift film formed on another transparent substrate under the conditions same as those mentioned above.

Next, the transparent substrate 1 provided with the phase shift film 2 was placed on a hot plate and subjected to heat treatment in air under the conditions of a heating temperature of 280° C. and a treatment time of 30 minutes. After the heat treatment, natural cooling was carried out in air down to ordinary temperature (25° C. or less).

For the phase shift film 2 after the heat treatment and the cooling mentioned above, a transmittance and a phase difference with respect to ArF excimer laser light (wavelength: 193 nm) were measured by a phase shift amount measurement apparatus (MPM-193 manufactured by Lasertec Corporation). As a result, the transmittance was 16.9% and the phase difference was 176.1 degrees.

Next, for the phase shift film 2 after the heat treatment and the cooling mentioned above, analysis of in-depth distribution of a secondary ion intensity of silicon was carried out by secondary ion mass spectrometry in the manner similar to Example 1. The measurement conditions are similar to those in Example 1. Measurement of the secondary ion intensity of silicon for the phase shift film 2 in Comparative Example was carried out at measurement intervals of 0.54 nm on average in a depth direction. In the phase shift film 2 of Comparative Example, the in-depth distribution of the secondary ion intensity of silicon obtained as a result of the analysis has a tendency that the secondary ion intensity reaches a peak in a region (surface region) from the surface of the phase shift film 2 to a depth of 10 nm, thereafter falls down once, and gradually increases therefrom towards the transparent substrate in a subsequent internal region. Furthermore, the secondary ion intensity considerably decreases in a region (substrate neighborhood region) extending over a range of 10 nm from the interface with the transparent substrate towards the surface region. This tendency is substantially same as those in Example 1 and Example 2 mentioned above. However, a degree (slope) of increase of the secondary ion intensity in the internal region towards the transparent substrate is slightly greater in Comparative Example than in Example 1 and Example 2.

From the result of the in-depth distribution of the secondary ion intensity of silicon in the phase shift film 2 of Comparative Example, distribution of the secondary ion intensity of silicon with respect to a depth from a film surface was plotted at a plurality of positions in the internal region of the phase shift film 2 except the surface region and the substrate neighborhood region (FIG. 7). Furthermore, from the result thereof, the degree of increase (slope of increase) of the secondary ion intensity [Counts/sec] of silicon in the internal region of the phase shift film 2 with respect to a depth [nm] in the direction towards the transparent substrate was calculated by applying the least-square method (a model is a linear function). As a result, the degree was 167.3 [(Count/sec)/nm] which did not satisfy the condition of this disclosure that the slope is less than 150 [(Counts/sec)/nm].

Next, the phase shift film 2 of Comparative Example was formed on another transparent substrate 1. In the manner similar to that mentioned above, heat treatment and cooling were carried out. The phase shift film 2 after the heat treatment and the cooling had a transmittance of 16.9% and a phase difference of 176.1 degrees with respect to the ArF excimer laser light (wavelength: 193 nm), which were same as those mentioned above.

Subsequently, the transparent substrate 1 provided with the phase shift film 2 was placed in a single-wafer DC sputtering apparatus and a light shielding film 3 of a chromium-based material having a single layer structure, which is similar to that in Example 1, was formed on the phase shift film 2. Specifically, the light shielding film 3 comprising a CrOC film and having a single layer structure was formed to a thickness of 56 nm.

A layered structure of the phase shift film 2 and the light shielding film 3 had an optical density of 3.0 or more at the wavelength (193 nm) of the ArF excimer laser.

Furthermore, the transparent substrate 1 with the phase shift film 2 and the light shielding film 3 formed as layers was placed in a single-wafer sputtering apparatus and a hard mask film 4 consisting of silicon and oxygen similar to that in Example 1 was formed on the light shielding film 3 to a thickness of 5 nm.

As described above, the mask blank 10 in Comparative Example was manufactured in which the phase shift film 2, the light shielding film 3, and the hard mask film 4 were formed as layers on the transparent substrate 1 in this order.

Next, using the mask blank 10, a transfer mask (phase shift mask) 20, in Comparative Example in which a fine pattern 2a of the phase shift film to serve as a transfer pattern was provided on the transparent substrate 1, was manufactured according to the above-mentioned manufacturing process illustrated in FIGS. 3A-3F and in the manner similar to Example 1 mentioned above.

The exposure light transmittance and the phase difference of the phase shift film pattern 2a were not changed from those at the time of manufacture of the mask blank.

The above-mentioned transfer mask 20 in Comparative Example thus obtained was subjected to inspection of a mask pattern by a mask inspection apparatus. As a result, it was confirmed that a fine pattern was formed in an allowable range from a designed value.

In the transfer mask 20 in Comparative Example thus obtained, an area of the phase shift film pattern 2a where a light shielding zone pattern 3b was not formed as a layer was subjected to intermittent irradiation with the ArF excimer laser light so that a cumulative irradiation amount was equal to 40 kJ/cm².

The transmittance and the phase difference of the phase shift film pattern 2a after the above-mentioned irradiation were measured. As a result, for the ArF excimer laser light (wavelength: 193 nm), the transmittance was 20.3% and the phase difference was 169.8 degrees. Therefore, variation amounts before and after the irradiation were +3.4% for the transmittance and −6.3 degrees for the phase difference. Thus, the variation amounts were large and the variation amounts of such levels seriously affect mask performance. Furthermore, it was confirmed that variation (CD variation) in line width of the phase shift film pattern 2a before and after the irradiation was equal to 5 nm.

From the foregoing, it is understood that, in the mask blank and the transfer mask of Comparative Example, when the thin film (phase shift film) of a SiN-based material is analyzed by secondary ion mass spectrometry to obtain the in-depth distribution of the secondary ion intensity of silicon, the slope of the secondary ion intensity [Counts/sec] of silicon with respect to the depth [nm] in the direction towards the transparent substrate is 150 [(Counts/sec)/nm] or more in the internal region of the thin film except the substrate neighborhood region and the surface region and that, in this case, there is no effect of improving the lightfastness against cumulative irradiation with the exposure light having a short wavelength of 200 nm or less such as the ArF excimer laser.

While the embodiment and the examples of this disclosure have thus far been described, they are merely for illustration purpose and do not limit the scope of the claims.

### EXPLANATION OF REFERENCE NUMERALS

1 transparent substrate
2 phase shift film
3 light shielding film
4 hard mask film
5a, 6a resist pattern
10 mask blank
20 transfer mask (phase shift mask)

1. A mask blank comprising:
a transparent substrate; and
a thin film provided on the transparent substrate to form a transfer pattern is provided,
wherein the thin film consists of silicon and nitrogen or consists of silicon, nitrogen, and at least one element selected from boron, germanium, antimony, tellurium, carbon, hydrogen, oxygen, phosphorus, sulfur, selenium, halogens, and noble gases, and
wherein a surface region of the thin film includes a surface of the thin film that faces away from the transparent substrate, and
wherein a neighborhood region of the thin film includes an interface of the thin film with the transparent substrate, and
wherein an internal region of the thin film lies between the neighborhood region and the surface region, and
wherein, when the thin film is analyzed by secondary ion mass spectrometry to obtain in-depth distribution of a secondary ion intensity of silicon in counts per second, a slope of the secondary ion intensity of silicon with respect to depth in a direction towards the transparent substrate is less than one hundred fifty counts per second per nanometer in the internal region of the thin film.

2. The mask blank according to claim 1, wherein the surface region extends from the surface of the thin film that faces away from the transparent substrate to a depth of 10 nm towards the transparent substrate.

3. The mask blank according to claim 1, wherein the neighborhood region extends from the interface with the transparent substrate to a depth of 10 nm towards the surface region.

4. The mask blank according to claim 1, wherein the in-depth distribution of the secondary ion intensity of silicon is obtained under measurement conditions that a primary ion species is Cs⁺, a primary accelerating voltage is 2.0 kV, and a primary ion irradiation area is an inside region of a square of 120 μm on a side.

5. The mask blank according to claim 1, wherein an oxygen content of the surface region is greater than an oxygen content of the rest of the thin film.

6. The mask blank according to claim 1, wherein the thin film consists of silicon, nitrogen, and at least one element selected from carbon, hydrogen, oxygen, phosphorus, sulfur, selenium, halogens, and noble gases.

7. The mask blank according to claim 6, wherein a nitrogen content of the thin film is 50 atomic % or more.

8. The mask blank according to claim 1, wherein the thin film is a phase shift film, and
wherein a transmittance of the phase shift film with respect to light of an ArF excimer laser having a wavelength of 193 nanometers is 1% or more, and
wherein the phase shift film is configured to shift a phase of light of an ArF excimer laser having a wavelength of 193 nanometers, when transmitted through the phase shift film, by a phase shift amount of 150 degrees or more and 190 degrees or less, the phase shift amount being relative to a phase of light of an ArF excimer laser having a wavelength of 193 nanometers transmitted through air for the same distance as a thickness of the phase shift film.

9. The mask blank according to claim 8, comprising a light shielding film formed on the phase shift film.

10. The mask blank according to claim 9, wherein the light shielding film contains chromium.

11. A transfer mask comprising:
a transparent substrate; and
a thin film having a transfer pattern provided on the transparent substrate,
wherein the thin film consists of silicon and nitrogen or consists of silicon, nitrogen, and at least one element selected from boron, germanium, antimony, tellurium, carbon, hydrogen, oxygen, phosphorus, sulfur, selenium, halogens, and noble gases, and
wherein a surface region of the thin film includes a surface of the thin film that faces away from the transparent substrate, and
wherein a neighborhood region of the thin film includes an interface of the thin film with the transparent substrate, and
wherein an internal region of the thin film lies between the neighborhood region and the surface region, and
wherein, when the thin film is analyzed by secondary ion mass spectrometry to obtain in-depth distribution of a secondary ion intensity of silicon in counts per second, a slope of the secondary ion intensity of silicon with respect to depth in a direction toward the transparent substrate is less than one hundred fifty counts per second per nanometer in the internal region of the thin film.

12. (canceled)

13. A method of manufacturing a semiconductor device, comprising exposure-transferring a transfer pattern to a resist film on a semiconductor substrate by using the transfer mask according to claim 11.

14. The transfer mask according to claim 11, wherein the surface region extends from the surface of the thin film that faces away from the transparent substrate to a depth of 10 nm toward the transparent substrate.

15. The transfer mask according to claim 11, wherein the neighborhood region extends from the interface with the transparent substrate to a depth of 10 nm towards the surface region.

16. The transfer mask according to claim 11, wherein the in-depth distribution of the secondary ion intensity of silicon is obtained under measurement conditions that a primary ion species is Cs⁺, a primary accelerating voltage is 2.0 kV, and a primary ion irradiation area is an inside region of a square of 120 μm on a side.

17. The transfer mask according to claim 11, wherein an oxygen content of the surface region is greater than an oxygen content of the rest of the thin film.

18. The transfer mask according to claim 11, wherein the thin film consists of silicon, nitrogen, and at least one element selected from carbon, hydrogen, oxygen, phosphorus, sulfur, selenium, halogens, and noble gases.

19. The transfer mask according to claim 11, wherein a nitrogen content of the thin film is 50 atomic % or more.

20. The transfer mask according to claim 11, wherein the thin film is a phase shift film, and
wherein a transmittance of the phase shift film with respect to light of an ArF excimer laser having a wavelength of 193 nanometers is 1% or more, and
wherein the phase shift film is configured to shift a phase of light of an ArF excimer laser having a wavelength of 193 nanometers, when transmitted through the phase shift film, by a phase shift amount of 150 degrees or more and 190 degrees or less, the phase shift amount being relative to a phase of light of an ArF excimer laser having a wavelength of 193 nanometers transmitted through air for the same distance as a thickness of the phase shift film.

21. The transfer mask according to claim 11, comprising a light shielding film having a pattern including a light shielding zone formed on the phase shift film.

22. The transfer mask according to claim 11, wherein the light shielding film contains chromium.
